(19) United States
(12) Patent Application Publication
(10) Pub. No.: US 2022/0277936 A1
(43) Pub. Date: Sep. 1, 2022

(54) PROTECTIVE MULTILAYER COATING FOR PROCESSING CHAMBER COMPONENTS

(71) Applicant: Applied Materials, Inc., Santa Clara, CA (US)

(72) Inventors: Geetika BAJAJ, New Delhi (IN); Yogita PAREEK, San Jose, CA (US); Darshan THAKARE, Thane West (IN); Prerna Sonthalia GORADIA, Mumbai (IN); Ankur KADAM, Thane (IN); Kevin A. PAPKE, Portland, OR (US)

(21) Appl. No.: 17/625,179

(22) PCT Filed: Jun. 22, 2020
(86) PCT No.: PCT/US2020/038873

§ 371 Date: Jan. 6, 2022

(30) Foreign Application Priority Data
Aug. 9, 2019 (IN) 201941032296

(51) Int. Cl. H01J 37/32; C23C 16/34; C23C 16/30; C23C 16/40; C23C 16/455; C23C 16/44; C23C 16/56; C23C 16/50

(52) U.S. Cl. CPC H01J 37/32495; C23C 16/34; C23C 16/308; C23C 16/403; C23C 16/405; C23C 16/45553; C23C 16/45527; C23C 16/4408; C23C 16/56; C23C 16/50; H01L 21/68757

(57) ABSTRACT

The present disclosure relates to protective multilayer coatings for processing clumbers and processing clumber components. In one embodiment, a multilayer protean e coating includes a metal nitride layer and an oxide layer disposed thereon. In one embodiment, the multilayer protective coating further includes an oxynitride interlayer and/or an oxy fluoride layer. The multilayer protective coating may be formed on a metal alloy or ceramic substrate, such as a processing clumber or a processing clumber component used in tire field of electronic device manufacturing, e.g., semiconductor device manufacturing. In one embodiment, the metal nitride layer and the oxide layer are deposited on the substrate by atomic layer deposition.

### BACKGROUND

### Field

Embodiments of the present disclosure generally relate to protective coatings. In particular, embodiments of the present disclosure relate to methods and apparatus for forming protective multilayer stacks for processing chambers and chamber components used in the field of semiconductor device manufacturing.

### Description of the Related Art

Often, semiconductor device processing equipment and components thereof, such as processing chamber bodies and processing chamber components, are formed of metal alloys or ceramic materials. The materials for such equipment and components are selected to provide desirable mechanical and chemical properties, namely tensile strength, density, ductility, formability, workability, and corrosion resistance. In addition to the primary elements of aluminum, carbon, iron, silicon, and yttrium, among others, the materials utilized in processing chamber components typically include additional elements such as cobalt, copper, chromium, magnesium, manganese, nickel, tin, tungsten, zinc, and combinations thereof. These additional elements are chosen to desirably improve the mechanical, and/or chemical properties of the resulting equipment or component.

Unfortunately, during semiconductor substrate processing, e.g., silicon wafer processing, the additional elements may undesirably migrate from the processing chamber or processing chamber component surfaces to other surfaces. For example, trace metals will migrate to surfaces of the substrates being processed in the processing chamber, thus resulting in trace metal contamination on substrate surfaces. Trace metal contamination is detrimental to electronic devices, e.g., semiconductor devices, formed on the substrate, often rendering the devices non-functional, contributing to degradation in device performance, and/or shortening the usable lifetime thereof.

Conventional methods of preventing the migration or leaching of elements from processing chamber and processing chamber component surfaces include coating the surfaces with a barrier layer. Often, the barrier layers formed on such surfaces tend to corrode well before the end of the useful lifetime of the processing chamber or processing chamber component due to the reactive or corrosive nature of environments present within processing chambers during substrate processing. Corrosion of the barrier layer forms undesirable particles within the processing chamber and undesirably exposes the equipment or component surface therebeneath. Like the trace metals described above, the particles can migrate to the surfaces of the substrate and render the devices formed thereon unsuitable for their intended purpose.

Accordingly, what is needed in the art are improved protective coatings for processing chamber surfaces and processing chamber components and methods of forming the same.

### SUMMARY

The present disclosure generally relates to protective coatings for processing chamber surfaces and processing chamber components and methods of forming the same.

In one embodiment, a chamber component for use in a plasma processing chamber is provided. The chamber component includes a surface formed of a metal alloy or ceramic and a coating disposed on the surface. The coating further includes a metal nitride layer and an oxide layer disposed on the metal nitride layer.

In one embodiment, a processing component is provided. The processing component includes a substrate formed of a metal alloy or ceramic, a metal nitride layer disposed on the substrate, an oxynitride layer disposed on the metal nitride layer, and an oxide layer disposed on the oxynitride interlayer.

In one embodiment, a method of forming a coating on a chamber component is provided. The method includes depositing a metal nitride layer on a surface of the chamber component and depositing an oxide layer on the metal nitride layer.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and the disclosure may admit to other equally effective embodiments.

FIG. 1 illustrates a cross-sectional schematic view of an exemplary processing chamber according to an embodiment described herein.

FIG. 2A schematically illustrates a cross-sectional view of a protective multilayer coating according to an embodiment described herein.

FIG. 2B schematically illustrates a cross-sectional view of a protective multilayer coating according to an embodiment described herein.

FIG. 3 illustrates a flow diagram of a method of depositing a protective multilayer coating on a substrate according to an embodiment described herein.

FIG. 4 illustrates a flow diagram of a method of depositing a protective multilayer coating on a substrate according to an embodiment described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to protective multilayer coatings for processing chambers and processing chamber components. In one embodiment, a multilayer protective coating includes a metal nitride layer and an oxide layer disposed thereon. In one embodiment, the multilayer protective coating further includes an oxynitride interlayer and/or an oxyfluoride layer. The multilayer protective coating may be formed on a metal alloy or ceramic substrate, such as a processing chamber or a processing chamber component used in the field of electronic device manufacturing, e.g., semiconductor device manufacturing. In one embodiment, the metal nitride layer and the oxide layer are deposited on the substrate by atomic layer deposition.

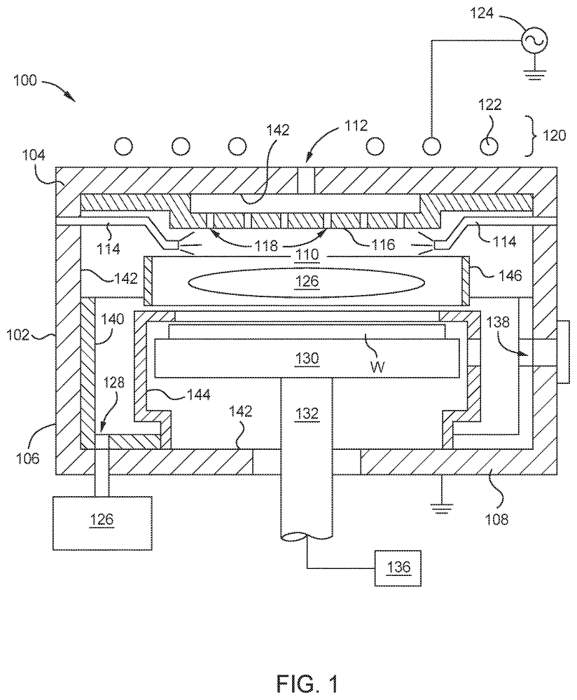

FIG. 1 is a cross-sectional schematic view of an exemplary processing chamber and examples of processing components that may be utilized therewith, according to one embodiment. FIG. 1 depicts a processing chamber 100 having various processing components that are utilized with high temperature processing chambers, such as plasma enhanced deposition chambers and plasma enhanced etch chambers. However, it is further contemplated that the protective multilayer coatings described herein may be utilized for any processing chamber, processing component, or substrate surface where enhanced thermal resistance and diffusion reduction is desired.

The processing chamber 100 includes a chamber body 102 having a chamber lid 104, one or more sidewalls 106, and a chamber bottom 108 at least partially defining a processing volume 110. In one embodiment, processing gases are delivered to the processing volume 110 through one or more inlets 112 disposed through the chamber lid 104, through one or more gas injection ports 114 disposed through the one or more sidewalls 106, or both. In some embodiments, the chamber lid 104 is coupled to a showerhead 116 having a plurality of apertures 118 disposed therethrough for uniformly distributing the processing gases into the processing volume 110.

As depicted in FIG. 1, the processing chamber 100 includes an inductively coupled plasma (ICP) coil assembly 120 disposed proximate to the chamber lid 104. The ICP coil assembly 120 includes one or more inductive coil antennas 122 driven by an RF power generator 124. The ICP coil assembly 120 is utilized to ignite and maintain a plasma 126 from the processing gases flowed into the processing volume 110 by using an electromagnetic field generated by the inductive coil antennas 122. In another embodiment, the processing chamber 100 includes a capacitively coupled plasma (CCP) assembly or a microwave plasma generator. For example, the RF power generator 124 may be directly coupled to the showerhead 116 to generate a capacitively coupled plasma within the processing volume 110. In yet another embodiment, the processing chamber 100 includes a remote plasma source (not shown) to generate a plasma remotely from the processing volume 110 before being delivered thereto.

In one embodiment, the processing volume 110 is coupled to vacuum source 162, such as a vacuum pump, through the exhaust port 128. The vacuum source 162 is configured to evacuate the processing gases, as well as other gases, from the processing volume 110 and maintain the processing volume 110 at sub-atmospheric conditions. A substrate support 130 is movably disposed in the processing volume 110 and is further coupled to a support shaft 132 that is sealingly extended through an opening 134 in the chamber bottom 108. In one embodiment, the support shaft 132 is surrounded by bellows (not shown) in a region below the chamber bottom 108. The support shaft 132 is further coupled to a lift servo 136 to actuate the support shaft 132, and therefore the substrate support 130, through the processing volume 110. In one embodiment, the substrate support 130 is movable from a first position to a second position within the processing volume 110 to facilitate transfer of a substrate W to and from the substrate support 130 through a slit valve 138 in the one or more sidewalls 106.

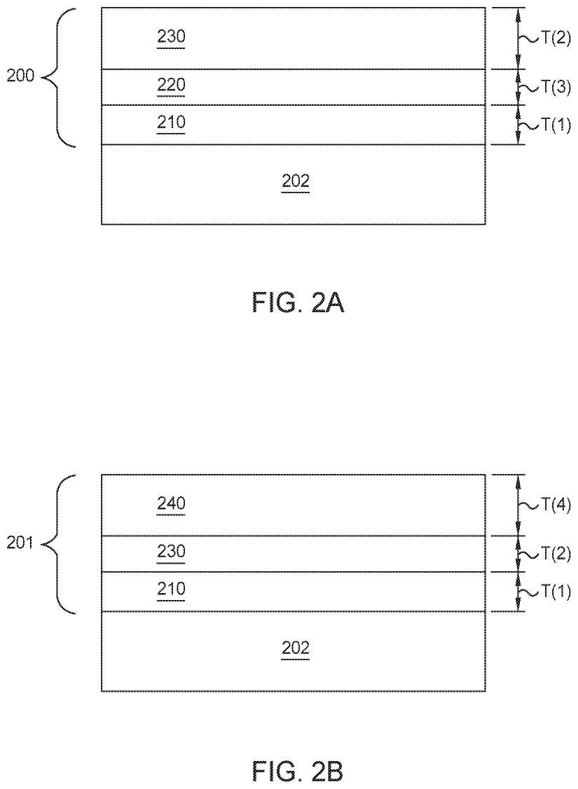

The processing chamber 100 includes one or more removable liners 140 disposed along and radially inward from one or more interior surfaces 142 of the chamber body 102. In some embodiments, the processing chamber 100 further includes one or more shields, such as the first shield 144 and the second shield 146. As depicted in FIG. 1, the first shield 144 circumscribes the substrate support 130 and the support shaft 132 and the second shield 146 is disposed above the first shield 144 and radially inward of the one or more sidewalls 106. The shields 144, 146 may be utilized to confine the plasma 126 to a desired region of the processing volume 110, to define flow pathways for the processing gases in the processing volume 110, or combinations thereof. In some embodiments, the one or more components described above, e.g., the chamber body 102 and the processing components disposed therein or utilized therewith, are formed of a metal alloy or ceramic and comprise a protective multilayer coating, such as those described with reference to FIGS. 2A and 2B.

FIG. 2A illustrates a protective multilayer coating 200 formed on a substrate 202 according to one embodiment. The protective multilayer coating 200 prevents leaching of the trace metals from the substrate 202 while also improving resistance to attack by the reactive or corrosive environments regularly presented within processing chambers, such as the processing chamber 100. Thus, deterioration of the underlying equipment or component and leaching of trace metals thereof can be reduced or avoided. Typically, the substrate 202, or a surface thereof, is formed of a ceramic or metal alloy. For example, the substrate 202 may comprise silicon (Si), silicon carbide (SiC), alumina (Al₂O₃), pyrolytic boron nitride (PBN), yttria (Y₂O₃), and the like. In another example, the substrate 202 may comprise aluminum (Al), chromium (Cr), copper (Cu), iron (Fe), magnesium (Mg), manganese (Mn), tin (Sn), and zinc (Zn). The substrate 202 may be any type of processing chamber equipment or a component thereof, including but not limited to those described in FIG. 1, as well as a lift pin, heater, electrostatic chuck, edge ring, dome, or other processing chamber component.

As shown in FIG. 2A, the protective multilayer coating 200 includes a metal nitride layer 210 disposed on the substrate 202 and an oxide layer 230 disposed over the metal nitride layer 210. In some embodiments, the metal nitride layer 210 comprises one or more of aluminum nitride (AlN), titanium nitride (TiN), tantalum nitride (TaN), or the like. In some embodiments, the oxide layer 230 comprises one or more of aluminum oxide (Al₂O₃), lanthanum oxide (La₂O₃), hafnium oxide (HfO₂), yttrium oxide (Y₂O₃), zirconium oxide (ZrO₂), cerium oxide (CeO₂), titanium oxide (TiO₂), or the like. In further embodiments, the protective multilayer coating 200 includes an oxynitride interlayer 220 formed between the metal nitride layer 210 and the oxide layer 230. The oxynitride interlayer 220 may be formed by annealing the protective multilayer coating 200 after formation of the oxide layer 230, thus creating an interfacial layer between the oxide layer 230 and the metal nitride layer 210.

The individual layers of the protective multilayer coating 200 generally have a thickness between about 1 nm and about 1500 nm. For example, the metal nitride layer 210 has a first thickness T(1) of less than about 250 nm, such as between about 1 nm and about 225 nm. In some embodiments, the thickness T(1) of the metal nitride layer 210 is between about 10 nm and about 200 nm, such as between about 25 nm and about 175 nm, between about 40 nm and about 160 nm, between about 50 nm and about 150 nm, between about 75 nm and about 125 nm, or between about 90 nm and about 110 nm. For example, the thickness T(1) of the metal nitride layer 210 is about 100 nm. In one example, the oxide layer 230 has a second thickness T(2) of between about 1 nm and about 1250 nm, such as between about 10 nm and about 1000 nm. In some embodiments, the thickness T(2) of the oxide layer 230 is between about 20 nm and about 900 nm, such as between about 50 nm and about 800 nm, between about 100 nm and about 700 nm, between about 200 nm and about 600 nm, or between about 300 nm and about 500 nm. For example, the thickness T(2) of the oxide layer 230 is about 400 nm. In a further embodiment, the oxynitride interlayer 220 has a third thickness T(3) between about 0.5 nm and about 10 nm, such as between about 1 nm and about 8 nm. For example, the oxynitride interlayer 220 has a third thickness T(3) between about 2 nm and about 6 nm, such as about 4 nm.

FIG. 2B illustrates a protective multilayer coating 201 formed on the substrate 202, such as a processing component described in FIG. 1 above, according to one embodiment. Here, the protective multilayer coating 201 includes the metal nitride layer 210 and the oxide layer 230 described in FIG. 2A. The protective multilayer coating 201 further includes an optional oxyfluoride layer 240 disposed on the oxide layer 230 to improve corrosion resistance of the protective multilayer coating 201. The oxyfluoride layer 240 is formed by fluorinating the oxide layer 230 after formation of the oxide layer 230 thereof. For example, the oxyfluoride layer 240 is formed by exposing a surface of the deposited oxide layer 230 to a fluorine-containing gas, such as hydrofluoric acid (HF), nitrogen trifluoride (NF₃), fluorine (F₂), NF₃ plasma, F radicals, and the like, at an elevated temperature for a time period. The time period may be about 0.1-24 hours in some embodiments. In one example, the oxyfluoride layer 240 has a fourth thickness T(4) of between about 1 nm and about 100 nm, such as between about 10 nm and about 80 nm. For example, the oxynitride interlayer 220 has a third thickness T(3) between about 20 nm and about 70 nm, such as between about 30 nm and about 60 nm, such as between about 40 nm and about 50 nm.

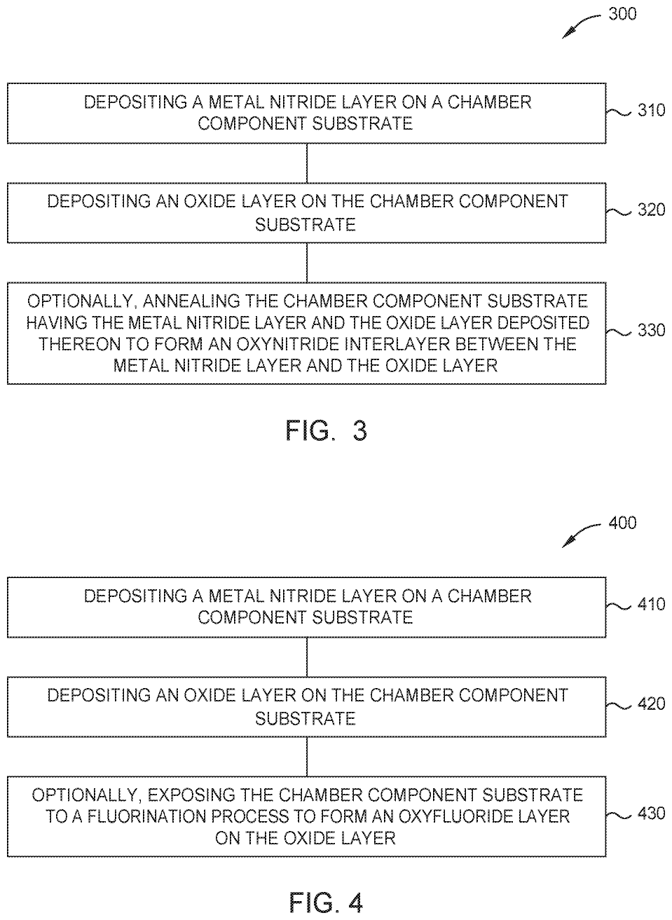

FIG. 3 is a flow diagram setting forth a method 300 of depositing a protective multilayer coating on a substrate within a processing chamber according to one embodiment. The method 300 may be used to form any one or a combination of protective multilayer coatings described in FIGS. 2A-2B on any one or a combination of processing components, such as the chamber body 102 and the processing components utilized therewith, as described in FIG. 1.

At operation 310, the method 300 includes depositing a metal nitride layer on a substrate. The metal nitride layer may be metal nitride layer 210 and the substrate may be substrate 202. In one example, the metal nitride layer may comprise one or more of aluminum nitride, titanium nitride, tantalum nitride, or the like. In some embodiments, the metal nitride layer 210 is deposited using a coating process that includes high temperature evaporation and sputtering, such as atomic layer deposition (ALD), plasma enhanced ALD (PEALD), physical vapor deposition (PVD), plasma enhanced PVD (PEPVD), chemical vapor deposition (CVD), plasma enhanced CVD (PECVD), hybrid CVD, electron beam vaporization, or other suitable process for depositing a coating on processing equipment or a processing component thereof.

In one embodiment, the metal nitride layer is deposited using an ALD process comprising alternating exposure of the substrate to a first precursor and a second precursor. For example, the first precursor is a metal-containing precursor and the second precursor is a nitrogen-containing precursor. The ALD process may be advantageously performed if the substrate exhibits a non-planar topography as a result of the conformality of an ALD process. The ALD process is also appropriate for deposition on substantially planar surfaces.

In one embodiment, the first precursor includes any suitable metal-containing precursor for forming the metal nitride film, such as aluminum, titanium, tantalum, and the like. In some embodiments, the first metal-containing precursor is selected from the group comprising (tert-butylimido)tris(diethylamido)tantalum (TBTDET), tetrakis(diethylamido)titanium (TDEAT), tetrakis(dimethylamino)titanium (TDMAT), tetrakis(ethylmethylamido)titanium (TEMAT), trimethylaluminum (TMA), pentakis(dimethylamino)tantalum(V) (PDMAT), and combinations thereof. In some embodiments, the metal-containing precursor is free of fluorine. Examples of suitable second precursors include nitrogen-containing precursors such as ammonia (NH₃), hydrazine (N₂H₄), methylhydrazine (CH₃(NH)NH₂), dimethylhydrazine (C₂H₈N₂), t-butylhydrazine (C₄H₁₂N₂), pheylhydrazine (C₆H₈N₂), azoisobutane (C₄H₈N₂), ethylazide (CH₃N₃), and combinations thereof.

In some embodiments where the metal nitride layer 210 is deposited by an ALD process, the substrate 202 is heated prior to deposition of the metal nitride layer 210. For example, the substrate 202 is heated to a temperature within a range from about 100° C. to about 400° C., such as between about 200° C. and about 300° C., such as about 250° C. During deposition of the metal nitride layer 210, the processing chamber is heated to a temperature within a range from about 200° C. to about 350° C., such as between about 225° C. and about 325° C., for example, about 275° C. For thermal ALD processes, the processing chamber may be maintained at a temperature of between about 300° C. and about 350° C., such as about 325° C. For plasma ALD processes, the processing chamber may be maintained at a temperature of between about 200° C. and about 275° C., such as about 250° C.

The first precursor for the metal nitride layer is flowed into the process chamber at a flow rate within a range from about 200 sccm to about 1000 sccm, such as a flow rate between about 400 sccm and about 800 sccm. In some embodiments, the first precursor is introduced into the process chamber with a carrier gas, such as an inert gas like nitrogen. The first precursor may further be pulsed into the processing chamber. The word “pulse” used herein is intended to refer to a quantity of a particular compound that is intermittently or non-continuously introduced into a reaction zone of a processing chamber. A monolayer of the first precursor may be formed on the substrate as a result of the pulsing thereof. In some embodiments, the first precursor is pulsed into the processing chamber for a duration in the range of about 100 ms to about 10 s, such as between about 150 ms and about 800 ms, such as between about 200 ms and about 250 ms. The first precursor may be heated to a temperature of between about 25° C. and about 125° C. prior to being flowed into the processing chamber. For example, the first precursor may be heated to a temperature between about 40° C. and about 80° C., such as about 65° C.

After flowing the first precursor into the processing chamber, a first purge process may be performed to remove any residual first precursor in the processing chamber. The first purge process may include pulsing a purge gas, such as argon or nitrogen gas, into the processing chamber for a duration between about 500 ms and about 10 s, such as between about 1 s and about 5 s, for example, about 3 s.

The second precursor, such as a nitrogen-containing precursor, is then pulsed into the processing chamber for a duration between about 150 ms and about 30 s, such as between about 2 s and about 25 s, for example, about 10 s. The second precursor is flowed into the process chamber at a flow rate within a range from about 50 sccm to about 1000 sccm, such as between about 200 sccm and about 800 sccm. The second precursor may be heated to about room temperature prior to being flowed into the processing chamber. For example, the second precursor may be heated to a temperature between about 20° C. and about 25° C. In some embodiments, a plasma is generated in the processing chamber while a nitrogen-containing second precursor is flowed therein. The plasma may be generated by applying an RF power to a plasma generator, such as the ICP coil assembly 120 or CCP assembly described with reference to FIG. 1. For example, an NH₃ plasma RF generator may apply an RF power between about 100 W to about 300 W, such as about 200 W, and at a frequency between of 13.56 MHz to the ICP coil assembly or the CCP assembly.

A second purge process may be performed following the pulsing of the second precursor. The second purge process may be performed to remove any residual second precursor in the processing chamber. Similar to the first purge process, the second purge process may include pulsing a purge gas, such as argon, into the processing chamber for a duration between about 500 ms and about 60 s, such as between about 1 s and about 30 s, for example, about 15 s.

The pulsing of the first precursor and the second precursor into the processing chamber may be a cycle, and the cycle may include the first and second purge processes after flowing the first precursor into the processing chamber and after flowing the second precursor into the processing chamber. The cycle is repeated to grow the metal nitride layer. The number of cycles is based on the desired thickness of the final metal nitride layer. The growth rate of the metal nitride layer may range from about 0.2 A to about 2 A per cycle. For example, the growth rate of the metal nitride layer may be about 1 A per cycle, depending on the precursor materials utilized. A final thickness of the metal nitride layer may be between about 5 nm and about 250 nm, such as between about 10 nm and about 200 nm. For example, a final thickness of the metal nitride layer is between about 25 nm and about 175 nm, such as between about 50 nm and about 150 nm, between about 75 nm and about 125 nm, between about 90 nm and about 110 nm, such as about 100 nm.

At operation 320, the method 300 includes depositing an oxide layer on the metal nitride layer. The oxide layer may be the oxide layer 230 depicted in FIG. 2A or FIG. 2B. In one example, the oxide layer 230 may comprise one or more of aluminum oxide, lanthanum oxide, hafnium oxide, yttrium oxide, zirconium oxide, cerium oxide, or the like. In some embodiments, the oxide layer 230 is deposited utilizing a similar method to that of the metal nitride layer 210 that includes high temperature evaporation and sputtering. For example, the oxide layer 230 may be deposited by ALD, PEALD, PVD, PEPVD, CVD, PECVD, hybrid CVD, electron beam vaporization, or other suitable processes for depositing a coating on processing equipment or a processing component thereof.

In one embodiment, the oxide layer is deposited using an ALD process comprising alternating exposure of the substrate to a third precursor and a fourth precursor, similar to the ALD process utilized to form the metal nitride as described above. For example, the third precursor is a metal or ceramic-containing precursor and the fourth precursor is an oxygen-containing precursor. The third precursor includes any suitable metal precursor for forming the oxide film, such as TMA, TDEAT, TDMAT, tetrakis(dimethylamido)hafnium(Hf(NMe2)4) (TDMAH), tetrakis(dimethylamido)zirconium(Zr(NMe2)4) (TDMAZ), [Ce(thd)₄], [Ce(thd)₃phen], [Ce(Cp)3], [Ce(CpMe)3], [Ce(iprCp)3], and combinations thereof. Examples of suitable fourth precursors include oxygen-containing precursors such as nitrous oxide (N₂O), oxygen (O₂), ozone (O₃), steam (H₂O), carbon monoxide (CO), carbon dioxide (CO₂), and the like.

The substrate already having the metal nitride layer deposited thereon may be heated prior to deposition of the oxide layer. For example, the substrate 202 having the metal nitride layer 210 formed thereon is heated to a temperature between about 100° C. and about 400° C., such as between about 150° C. and about 350° C., for example, between about 200° C. and about 300° C. During deposition of the oxide layer 230, the processing chamber is heated to a temperature within a range from about 150° C. to about 300° C., such as between about 175° C. and about 275° C., for example, 200° C.

The third precursor is flowed into the process chamber at a flow rate within a range from about 200 sccm and about 1000 sccm, such as a flow rate between about 400 sccm and about 800 sccm. In some embodiments, the third precursor is introduced into the process chamber with a carrier gas, such as inert gas like nitrogen. In some embodiments, the third precursor utilized for formation of the oxide layer is pulsed into the processing chamber for a duration in the range of about 100 ms to about 10 s, such as between about 150 ms and about 800 ms, such as between about 200 ms and about 250 ms. The third precursor may be heated to a temperature of between about 25° C. and about 125° C. prior to being flowed into the processing chamber. For example, the third precursor may be heated to a temperature between about 40° C. and about 80° C., such as about 65° C.

After flowing the third precursor into the processing chamber, a third purge process may be performed to remove any residual third precursor in the processing chamber. Similar to the first and second purge processes, the third purge process may include pulsing a purge gas into the processing chamber for a duration of between about 500 ms and about 10 s, such as between about 1 s and about 5 s, for example, about 3 s.

The fourth precursor, such as an oxygen-containing precursor, is then pulsed into the processing chamber for a duration between about 150 ms and about 30 s, such as between about 2 s and about 25 s, for example, about 10 s. The fourth precursor is flowed into the process chamber at a flow rate between about 50 sccm and about 1000 sccm, such as between about 200 sccm and about 800 sccm. Similar to the second nitrogen-containing precursor, the fourth oxygen-containing precursor may be heated to a temperature of about room temperature prior to being flowed into the processing chamber, for example, between about 20° C. and about 25° C.

Following the pulsing of the fourth precursor, a fourth purge process may be performed to remove any residual fourth precursor in the processing chamber. Similar to the previous purge processes, the fourth purge process may include pulsing a purge gas into the processing chamber for a duration between about 500 ms and about 60 s, such as between about 1 s and about 30 s, for example, about 15 s.

The pulsing of the third precursor and the fourth precursor into the processing chamber may be a cycle, and the cycle may include the third and the fourth purge processes after flowing the third precursor into the processing chamber and after flowing the fourth precursor into the processing chamber. The cycle is repeated to grow the oxide layer. The number of cycles is based on the desired thickness of the final oxide layer. The growth rate per cycle may range from about 0.2 A to about 2 A per cycle, depending on the materials used for the third and fourth precursors. A final thickness of the oxide layer may be between about 10 nm and about 1 μm, such as between about 100 nm and about 750 nm. For example, a final thickness of the metal nitride layer is between about 150 nm and about 700 nm, such as between about 200 nm and about 600 nm, between about 300 nm and about 500 nm, between about 350 nm and about 450 nm, such as about 400 nm.

At operation 330, the method 300 optionally includes annealing the substrate having the metal nitride layer and the oxide layer formed thereon, such as the substrate 202 having the metal nitride layer 210 and the oxide layer 230 formed thereon. In one embodiment, the substrate 202 is exposed to a heating process having a temperature greater than about 200° C. For example, the substrate 202 is heated at a temperature within a range of about 275° C. to about 375° C., such as between about 300° C. and about 350° C., such as about 325° C. Annealing of the substrate 202 at operation 330 forms an oxynitride interlayer between the metal nitride layer and the oxide layer, such as the oxynitride interlayer 220, which further improves the performance and resistance of the protective multilayer coating.

FIG. 4 is a flow diagram setting forth a method 400 of depositing a protective multilayer coating on a substrate within a processing chamber according to one embodiment. The method 400 may be used to form any one or a combination of protective multilayer coatings described in FIGS. 2A-2B on any one or a combination of processing components, such as the chamber body 102 and the processing components utilized therewith, as described in FIG. 1.

Operations 410 and 420 are substantially similar to operations 310 and 320 and thus will not be described in further detail. At operation 430, however, unlike the method 300, the method 400 includes optionally fluorinating the substrate having the metal nitride layer and the oxide layer formed thereon, such as the substrate 202 having the metal nitride layer 210 and the oxide layer 230 formed thereon. In one embodiment, an oxyfluoride layer, such as the oxyfluoride layer 240, is formed by exposing the oxide layer 230 to a fluoride processing gas or plasma to convert a top portion of the oxide layer 230. In another embodiment, the oxyfluoride layer 240 is formed by exposing the substrate 202 to a fluoride ALD process, thus depositing a conformal oxyfluoride film on the oxide layer 230. The formation of the oxyfluoride layer 240 at operation 430 further improves the performance and corrosion resistance of the protective multilayer coating.

In summary, the protective multilayer coatings of the present disclosure are resistant to leaching of trace metals as well as attack (either chemically or physically) by reactive species within a semiconductor chamber processing environment, reducing deterioration and corrosion of materials thereunder. Thus, the metal nitride layer and the oxide layer disclosed herein provide improved protection for processing chamber equipment and components thereof by functioning as thermal and diffusion barriers.

While the foregoing is directed to embodiments of the present disclosure, other and further embodiments of the disclosure may be devised without departing from the basic scope thereof, and the scope thereof is determined by the claims that follow.

What is claimed is:

1. A chamber component for use in a plasma processing chamber, comprising:
a chamber component having a surface, the surface comprising a metal alloy or ceramic; and
a protective coating disposed on the surface of the chamber component, the protective coating comprising:
a metal nitride layer having a thickness of between about 10 nm and about 200 nm; and
an oxide layer disposed on the metal nitride layer and having a thickness of between about 1 nm and about 1 um, the metal nitride layer and the oxide layer deposited on the surface of the chamber component by an ALD process.

2. The chamber component of claim 1, further comprising an oxynitride interlayer having a thickness between about 0.5 nm and about 10 nm.

3. The chamber component of claim 1, further comprising an oxyfluoride layer having a thickness of between about 1 nm and about 100 nm.

4. The chamber component of claim 1, wherein the metal nitride layer comprises one or more of aluminum nitride, titanium nitride, and tantalum nitride.

5. The chamber component of claim 1, wherein the oxide layer comprises one or more of aluminum oxide, lanthanum oxide, hafnium oxide, yttrium oxide, zirconium oxide, cerium oxide, or titanium oxide.

6. The chamber component of claim 1, wherein the protective coating has a thickness between about 1 nm and about 1500 nm.

7. A method for forming a coating on a processing chamber component, comprising:
depositing a metal nitride layer on a surface of the processing chamber component via ALD, the metal nitride layer having a thickness of between about 10 nm and about 200 nm;
depositing an oxide layer on the metal nitride layer via ALD, the oxide layer having a thickness of between about 1 nm and about 1 um.

8. The method of claim 7, further comprising:
heating the surface of the processing chamber component to a temperature between about 200° C. and about 300° C. prior to depositing the metal nitride layer and the oxide layer.

9. The method of claim 7, wherein depositing the metal nitride layer further comprises:
flowing a first precursor into the processing chamber for a period of between about 150 ms and about 800 s, the first precursor heated to a temperature between about 40° C. and about 80° C., the first precursor comprising a metal-containing species; and
flowing a second precursor into the processing chamber for a period of between about 2 s and about 25 s, the second precursor heated to a temperature between about 20° C. and about 25° C., the second precursor comprising a nitrogen-containing species.

10. The method of claim 9, wherein the first precursor is selected from the group comprising TBTDET, TDEAT, TDMAT, TEMAT, TMA, and PDMAT.

11. The method of claim 9, wherein the second precursor is selected from the group comprising NH₃, N₂H₄, CH₃(NH)(NH₂), C₂H₈N₂, C₄H₁₂N₂, C₆H₈N₂, C₄H₈N₂, and CH₃N₃.

12. The method of claim 9, further comprising purging the processing chamber after flowing the first precursor into the processing chamber and after flowing the second precursor into the processing chamber.

13. The method of claim 7, wherein depositing the oxide layer further comprises:
flowing a third precursor into the processing chamber for a period of between about 150 ms and about 800 s, the third precursor heated to a temperature between about 40° C. and about 80° C., and
flowing a fourth precursor into the processing chamber for a period of between about 2 s and about 25 s, the fourth precursor heated to a temperature between about 20° C. and about 25° C., the fourth precursor comprising an oxygen-containing species.

14. The method of claim 13, wherein the third precursor is selected from the group comprising TMA, TDEAT, TDMAT, TDMAH, TDMAZ, [Ce(thd)₄], [Ce(thd)₃phen], [Ce(Cp)3], [Ce(CpMe)3], and [Ce(iprCp)3].

15. The method of claim 13, wherein the fourth precursor is selected form the group comprising N₂O, O₂, O₃, H₂O, CO, and CO₂.

16. The method of claim 7, further comprising:
annealing the metal nitride layer and the oxide layer to form an oxynitride interlayer therebetween.

17. The method of claim 7, further comprising:
exposing the oxide layer to a fluorine-containing gas to form an oxyfluoride layer thereon.

18. A method for forming a coating on a chamber component for use in a processing chamber, comprising:
depositing a metal nitride layer on a surface of a processing chamber component via a first ALD process, the first ALD process comprising:
heating the surface of the processing chamber component to a temperature between about 200° C. and about 300° C.,
flowing a first precursor into the processing chamber for a period of between about 150 ms and about 800 s, the first precursor heated to a temperature between about 40° C. and about 80° C., the first precursor comprising a metal-containing species; and
flowing a second precursor into the processing chamber for a period of between about 2 s and about 25 s, the second precursor heated to a temperature between about 20° C. and about 25° C., the second precursor comprising a nitrogen-containing species; and
depositing an oxide layer on the metal nitride layer via a second ALD process, the second ALD process comprising:
flowing a third precursor into the processing chamber for a period of between about 150 ms and about 800 s, the third precursor heated to a temperature between about 40° C. and about 80° C., and
flowing a fourth precursor into the processing chamber for a period of between about 2 s and about 25 s, the fourth precursor heated to a temperature between about 20° C. and about 25° C., the second precursor comprising an oxygen-containing species.

19. The method of claim 18, wherein the first precursor is selected from the group comprising TBTDET, TDEAT, TDMAT, TEMAT, TMA, and PDMAT, and the second precursor is selected from the group comprising NH₃, N₂H₄, CH₃(NH)(NH₂), C₂H₈N₂, C₄H₁₂N₂, C₆H₈N₂, C₄H₈N₂, and CH₃N₃.

20. The method of claim 18, wherein the third precursor is selected from the group comprising TMA, TDEAT, TDMAT, TDMAH, TDMAZ, [Ce(thd)₄], [Ce(thd)₃phen], [Ce(Cp)3], [Ce(CpMe)3], and [Ce(iprCp)3], and the fourth precursor is selected form the group comprising N₂O, O₂, O₃, H₂O, CO, and CO₂.
